(19) United States
(12) Patent Application Publication
(10) Pub. No.: US 2003/0036240 A1
(43) Pub. Date: Feb. 20, 2003

(54) Method of simultaneous formation of local interconnect and gate electrode

(76) Inventor: Jigish D. Trivedi, Boise, ID (US)

Correspondence Address: WHYTE HIRSCHBOECK DUDEK S.C., 111 E. WISCONSIN AVE., SUITE 2100, MILWAUKEE, WI, 53202, US

(21) Appl. No.: 09/932,863

(22) Filed: Aug. 17, 2001

(51) Int. Cl. H01L 21/20

(52) U.S. Cl. 438/383

(57) ABSTRACT

A method for the simultaneous formation of a gate electrode and a local interconnect or other interconnect structure in a semiconductor device is provided. In an embodiment of the method, an insulating layer disposed adjacent to a gate transistor is patterned to form an opening for the interconnect structure, and a sacrificial layer (e.g., silicon nitride) of the gate stack is removed to form a recess in the gate stack and expose an underlying conductive layer (e.g., polysilicon). A conductive material such as tungsten is deposited to simultaneously fill the recess of the gate stack and the opening in the insulating layer to form the interconnect structure. Exemplary interconnect structures include local interconnects, contacts, buried contacts, plugs, contact landing pads, and filled trenches.

### FIELD OF THE INVENTION

The invention relates generally to semiconductor devices, and more particularly to interconnections within semiconductor circuits and methods of making the interconnections.

### BACKGROUND OF THE INVENTION

Integrated circuits are interconnected networks of resistors, transistors and other electrical components that are generally formed on a silicon substrate or wafer with conductive, insulative and semiconductive materials. Fabricating integrated circuits involves forming electrical components at a number of layers and different locations. The interconnect structures are typically comprised of aluminum, tungsten, copper, gold, silver, polysilicon, or other suitably conductive material.

Sub-quarter micron, high-performance SRAM/logic systems require low resistance gate stacks and routinely use local interconnects. Conventional methods for forming wordlines and local interconnects require separate masking and etching steps, and separate polishing steps. It would be desirable to provide a method for fabricating these structures that reduces or eliminates processing steps.

### SUMMARY OF THE INVENTION

The present invention relates generally to semiconductor fabrication techniques and, more particularly, to the simultaneous formation of a gate electrode and a local interconnect or other interconnect structure.

In one aspect, the invention provides methods of forming an interconnect structure in a semiconductor device that comprises at least one transistor gate stack comprising a sacrificial layer (e.g., silicon nitride) overlying a first conductive layer (e.g., polysilicon), source/drain regions, and an insulating layer (e.g., BPSG) adjacent the transistor gate stack. An intervening layer (e.g., oxide, nitride) can be disposed between the sacrificial layer and the first conductive layer.

In one embodiment of the method, a portion of the insulating layer is patterned and removed to form an opening, the sacrificial layer of the gate stack is removed to form a recess over the first conductive layer, and a second conductive material (e.g., tungsten) is deposited to fill the recess of the transistor gate and the opening in the insulating layer to form the interconnect structure. Where the second conductive layer comprises tungsten, preferably a contact layer (e.g., titanium) and an overlying barrier layer (e.g., titanium nitride) are formed over the intervening layer, the source/drain regions and the insulating layer prior to depositing the tungsten layer. After depositing the second conductive material, an excess portion of the conductive material can be removed, for example by chemical-mechanical polishing, resulting in the interconnect structure and the gate stack. Exemplary interconnect structures include local interconnects, contacts, buried contacts, plugs, contact landing pads, and filled trenches.

In an embodiment of the method to form a local interconnect in electrical communication with the gate stack, a portion of the insulating layer adjacent to the gate stack is removed such that the resultant opening is in communication with the sacrificial layer of the gate stack.

In an embodiment of a method to form a contact landing pad that is interconnected to a source/drain region, a portion of the insulating layer adjacent to the gate stack is patterned to provide an opening that is isolated from the gate and is in communication with the source/drain region. In forming a pad interconnect, where an intervening layer (e.g., oxide, nitride) is disposed between the sacrificial layer and the first conductive layer, after removing the sacrificial layer and depositing a contact layer and barrier layer over the source/drain region prior to depositing the second conductive material (e.g., tungsten) into the opening to form the pad.

In another embodiment of a method according to the invention to form a transistor and an interconnect structure, a substrate comprising a gate dielectric layer formed thereon and a conductive layer formed over the gate dielectric layer is provided, a sacrificial layer (e.g., silicon nitride) is formed over the conductive layer, source/drain regions are at least partially formed, a pair of sidewall spacers (e.g., silicon dioxide) are formed laterally adjacent the conductive layer and sacrificial layer, an insulative layer is formed over the sacrificial layer and the source/drain regions, a portion of the insulative layer is removed to expose the sacrificial layer, an opening is patterned in the insulating layer for the interconnect structure, the sacrificial layer is removed to expose the conductive layer, and a layer predominately comprising elemental or alloy metal is formed over the conductive layer and into the opening of the insulating layer. An intervening layer (e.g., oxide, nitride, oxynitride) can be provided between the conductive layer and the sacrificial layer.

In another embodiment of a method of forming a transistor according to the invention, a gate dielectric layer, a first conductive layer, and a sacrificial layer (e.g., an insulative material) are sequentially formed over a semiconductor substrate and patterned into a transistor gate stack; insulative sidewall spacers are formed over sidewalls of the gate stack; an insulative layer is formed over the sacrificial layer and the source/drain regions; a portion of the insulative layer is removed to expose the sacrificial layer; an opening is patterned in the insulating layer for the interconnect structure; substantially all the sacrificial layer is removed from the gate stack between the spacers; and a conductive material (e.g., elemental or alloy metal) is simultaneously deposited between the spacers in electrical connection with the first conductive layer to form the transistor gate, and into the opening in the insulating layer to form the interconnect structure in electrical connection with the gate. Prior to forming the sacrificial layer, an intervening layer can be formed over the first conductive layer, whereby removing the sacrificial layer comprises etching the sacrificial layer substantially selective to the intervening layer, and all of the intervening layer is removed to expose the first conductive layer prior to depositing the second conductive material. Titanium (Ti) and titanium nitride (TiN) layers can be formed between the first conductive layer and the conductive material.

Advantageously, the methods of the present invention can be used to simultaneously form low resistance wordlines (gate electrodes) and interconnect structures such as local interconnects and contact landing pads. The present methods are readily integrated using conventional processing technologies, and eliminate at least one masking step and one W-CMP processing step over damascene W-wordlines and W-local interconnects that are formed separately. The methods of the invention also allow integration of conventional source/drain reoxidation as the gate electrode is formed.

### BRIEF DESCRIPTION OF THE DRAWINGS

Preferred embodiments of the invention are described below with reference to the following accompanying drawings, which are for illustrative purposes only. Throughout the following views, the reference numerals will be used in the drawings, and the same reference numerals will be used throughout the several views and in the description to indicate same or like parts.

FIG. 1 is a diagrammatic cross-sectional view of a semiconductor wafer at a preliminary step of a processing sequence according to an embodiment of the method of the invention.

FIG. 2 is a view of the FIG. 1 wafer fragment at a subsequent and sequential processing step.

FIG. 3 is a view of the FIG. 1 wafer fragment at a subsequent and sequential processing step to that shown by FIG. 2.

FIG. 4 is a view of the FIG. 1 wafer fragment at a processing step subsequent to that shown by FIG. 3.

FIG. 5 is a view of the FIG. 1 wafer fragment at a processing step subsequent to that shown by FIG. 4.

FIG. 6 is a view of the FIG. 1 wafer fragment at a processing step subsequent to that shown by FIG. 5.

FIG. 7 is a view of the FIG. 1 wafer fragment at a processing step subsequent to that shown by FIG. 6.

FIG. 8 is a view of the FIG. 1 wafer fragment at a processing step subsequent to that shown by FIG. 7.

FIG. 9 is a view of the FIG. 1 wafer fragment at a processing step subsequent to that shown by FIG. 8.

FIG. 10 is a view of the FIG. 1 wafer fragment at a processing step subsequent to that shown by FIG. 9.

FIG. 11 is a view of the FIG. 1 wafer fragment at a processing step subsequent to that shown by FIG. 10.

FIG. 12 is a view of the FIG. 1 wafer fragment at a processing step subsequent to that shown by FIG. 11.

### DETAILED DESCRIPTION OF THE PREFERRED EMBODIMENTS

The invention will be described generally with reference to the drawings for the purpose of illustrating the present preferred embodiments only and not for purposes of limiting the same. The figures illustrate processing steps for use in the fabrication of semiconductor devices in accordance with the present invention. It should be readily apparent that the processing steps are only a portion of the entire fabrication process.

In the current application, the terms “semiconductive wafer fragment” or “wafer fragment” or “wafer” will be understood to mean any construction comprising semiconductor material, including but not limited to bulk semiconductive materials such as a semiconductor wafer (either alone or in assemblies comprising other materials thereon), and semiconductive material layers (either alone or in assemblies comprising other materials). The term “substrate” refers to any supporting structure including, but not limited to, the semiconductive wafer fragments or wafers described above.

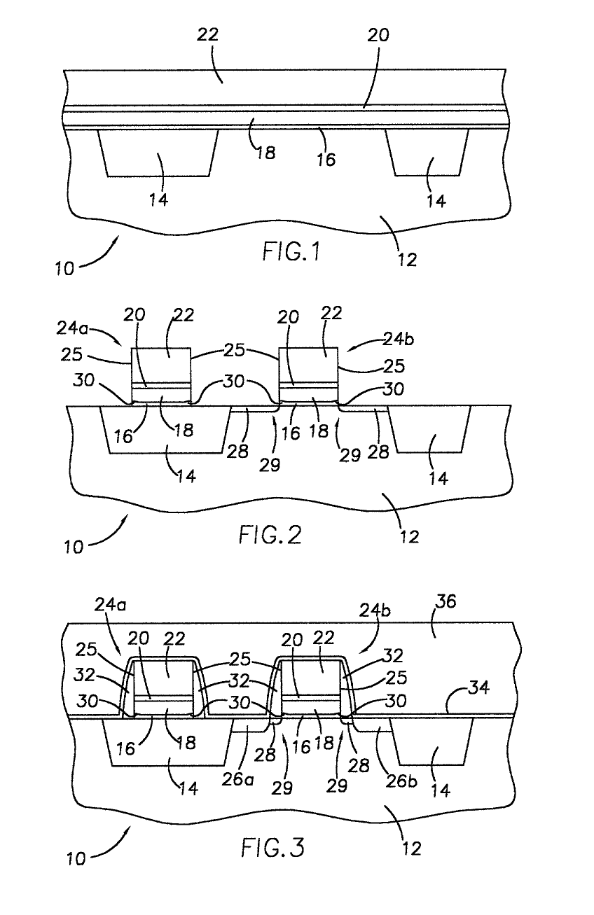

With reference to FIGS. 1-12, exemplary embodiments of the present invention are illustrated. FIG. 1 depicts a wafer fragment 10 comprising a substrate 12. Substrate 12 may comprise a bulk substrate material of semiconductive or semiconductor material, for example, monocrystalline silicon.

The substrate 12 is provided with isolation regions 14 formed therein, for example, shallow trench isolation regions. A gate dielectric layer 16, a first conductive layer 18 and a sacrificial layer 22 are sequentially formed over substrate 12. An exemplary gate dielectric layer 16 comprises an oxide. An exemplary first conductive layer 18 comprises elemental or alloy metal, or semiconductor material, for example, polysilicon. An exemplary sacrificial layer 22 may be electrically conductive, for example, polysilicon, or in one aspect of the invention, comprises an insulative material, for example, silicon nitride (Si₃N₄). The sacrificial layer 22 is selectively etchable relative to proximate materials formed subsequently. In another aspect of the invention, an optional intervening layer 20 is formed over the first conductive layer 18 prior to forming the sacrificial layer 18. The intervening layer 20 can comprise undoped oxide, nitride or oxynitride. An exemplary intervening layer 20 comprises oxide formed from a TEOS source or thermally grown from layer 18. Exemplary thicknesses for layers 16, 18, 20 and 22 are 30 angstroms, 1,000 angstroms, 200 angstroms and 1,500 angstroms, respectively.

Referring to FIG. 2, the gate dielectric layer 16, the first conductive layer 18, the intervening layer 20, and the sacrificial layer 22 are patterned to form transistor gate stacks 24a,b. The transistor gate stacks 24a,b comprise sidewalls 25. An exemplary method to form transistor gate stacks 24a,b comprises dry etching. A doped region 29 is at least partially formed by doping substrate 12 with a conductivity enhancing impurity. In one aspect of the invention, the method of doping comprises a plurality of ion implants with one exemplary implant forming lightly doped drain (LDD) regions 28.

The wafer fragment 10 can be exposed to at least one reoxidation step as desired. An exemplary purpose for performing a reoxidation step is to reoxidize existing oxide layers, e.g., layers 16 and 20, thereby enhancing the integrity of the layers. The reoxidation also forms a “gate bird's beak” in the layer 18 thereby reducing the overlap capacitance between the gate dielectric layer 16 and a layer 18.

Referring to FIG. 3, insulative sidewall spacers 32 are formed laterally adjacent the first conductive layer 18 and sacrificial layer 22 over the sidewalls 25 of the gate stacks 24. An exemplary material for the sidewall spacers 32 comprises undoped oxide, such as silicon dioxide formed from a tetraethylorthosilicate (TEOS) source. An exemplary method of forming the sidewall spacers 32 comprises providing an insulative material over the gate stacks 24a,b and anisotropically etching the insulating material to form the sidewall spacers 32 over sidewalls 25 of gate stacks 24a,b.

As also shown in FIG. 3, another one of the plurality of ion implants is performed in doped region 29 to form, for example, source/drain regions 26a,b. In one aspect of the invention, one of the plurality of ion implants comprises a highest dose compared to all other of the plurality of ion implants. Exemplary conductivity enhancing impurities comprise arsenic (As) and boron trifluoride (BF₃).

An etch stop layer 34 is formed over the substrate 12, sidewall spacers 32 and gate stacks 24a,b. The etch stop layer 34 typically comprises a thin layer of undoped oxide, nitride or oxynitride.

An insulative layer 36 is formed over the oxide layer 34. An exemplary insulative layer 36 comprises borophosphosilicate glass (BPSG). A rapid thermal process (RTP) is performed to reflow insulative layer 36 (i.e., BPSG) and activate source/drain regions 26a,b. An exemplary RTP comprises a temperature ramp rate of at least 50° C./second to achieve a temperature of at least about 950° C. for a 20 second annealing.

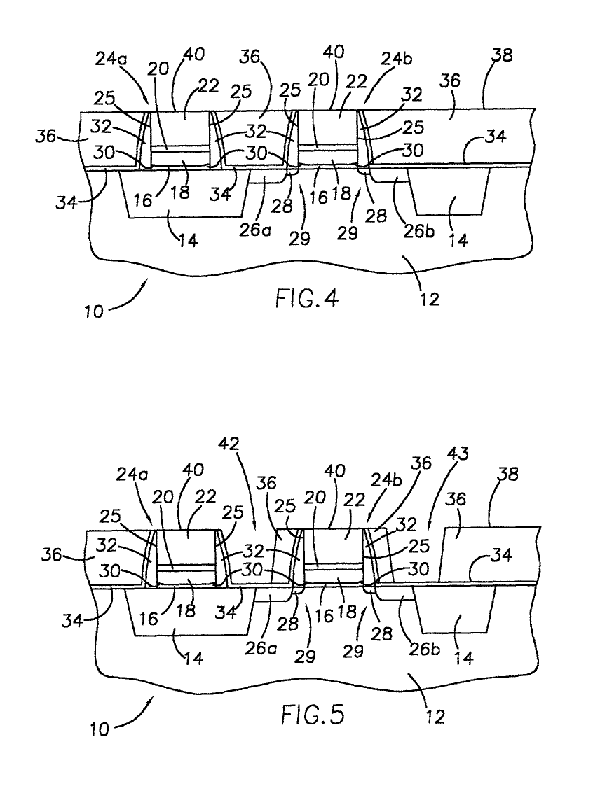

Referring to FIG. 4, portions of the insulative (e.g., BPSG) layer 36 are removed to form upper surface 38 thereby forming an exposed surface 40 of sacrificial layer 22. An exemplary method to remove portions of the insulative layer 36 comprises chemical mechanical polishing (CMP).

The present method provides for the formation of interconnect structures such as a local interconnect and/or contact landing pad simultaneously with the formation of the gate electrode. As shown in the exemplary structure in FIG. 5, with the sacrificial layer 22 (e.g., Si₃N₄) in place, a portion of the insulative (e.g., BPSG) layer 36 is removed to define an opening slot 42 adjacent to the gate stack 24a for the subsequent formation of a local interconnect 52, and to define an opening 43 to underlying source/drain structure 26b for the subsequent formation of an isolated pad structure 54. An exemplary method to remove portions of the insulative layer 36 comprises an oxide dry etch that is selective to the sacrificial layer 22 (e.g., nitride).

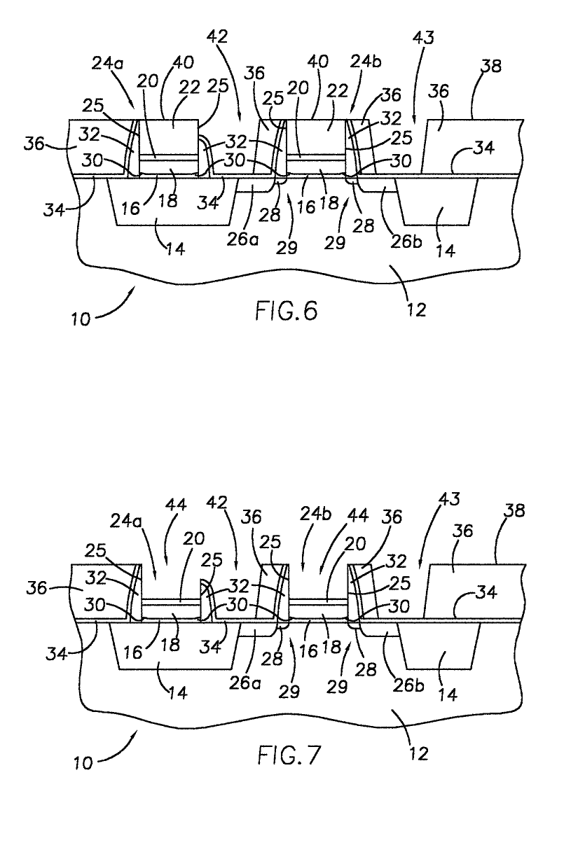

Referring to FIG. 6, a dry etch substantially selective to sacrificial layer 22 is used to remove and selectively etch a portion of the oxide layer 34 and spacer 32 to connect the slot 42 for the local interconnect to the gate stack 24a.

Referring to FIG. 7, the sacrificial layer 22 (e.g., Si₃N₄) is entirely removed from the gate stacks 24a,b between the sidewall spacers 32 to form recesses 44. An exemplary method to remove the sacrificial layer 22 comprises selectively etching the sacrificial layer 22 relative the sidewall spacers 32, intervening layer 20 and insulative layer 36. Where layer 22 comprises Si₃N₄, an example etch would use a conventional hot phosphoric acid (H₃PO₄) strip.

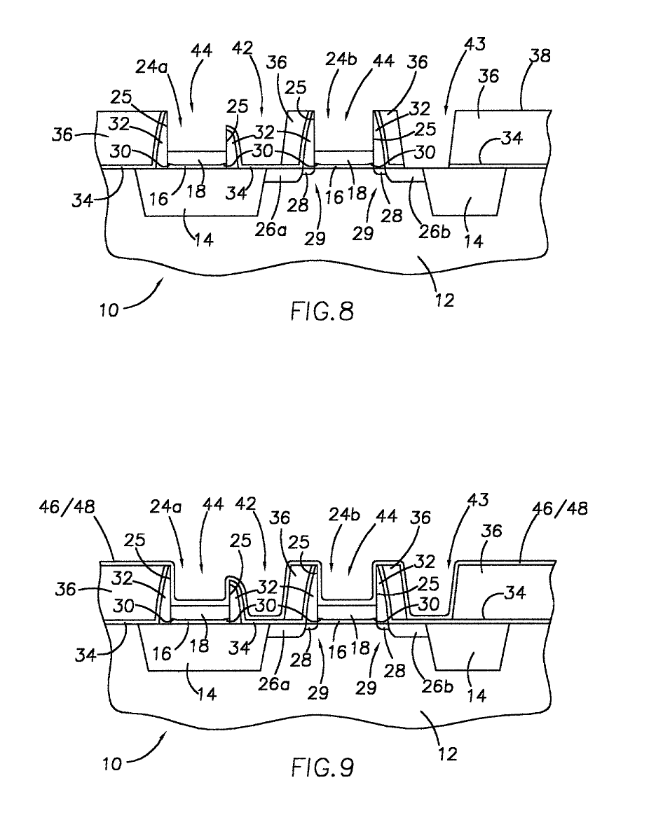

Referring to FIG. 8, a short punch etch is then conducted to remove the intervening layer 20 from exposed areas 42 and 44, to expose the first conductive layer (e.g., polysilicon) 18 of the gate stacks 24a, 24b and also to remove the etch stop layer (e.g., Si₃N₄) 34 from exposed area 43 overlying the source/drain regions 26b. An exemplary method to remove the intervening layer 20 and the etch stop layer 34 is a conventional sputter etch.

Referring to FIG. 9, a conductive contact layer 46 and overlying diffusion barrier layer 48 are formed within recesses 44 over the first conductive layer 18, the insulative layer 36, and the sidewall spacers 32. An exemplary contact layer 46 comprises a metal such as titanium (Ti), and an overlying barrier layer 46 comprises titanium nitride (TiN), each being formed by physical vapor deposition (PVD), e.g., sputtering, or by chemical vapor deposition (CVD). An anneal step (RTP) is then performed at about 700 to 750° C. in nitrogen (N₂) for about 20 seconds, to form good contact with the source/drain region.

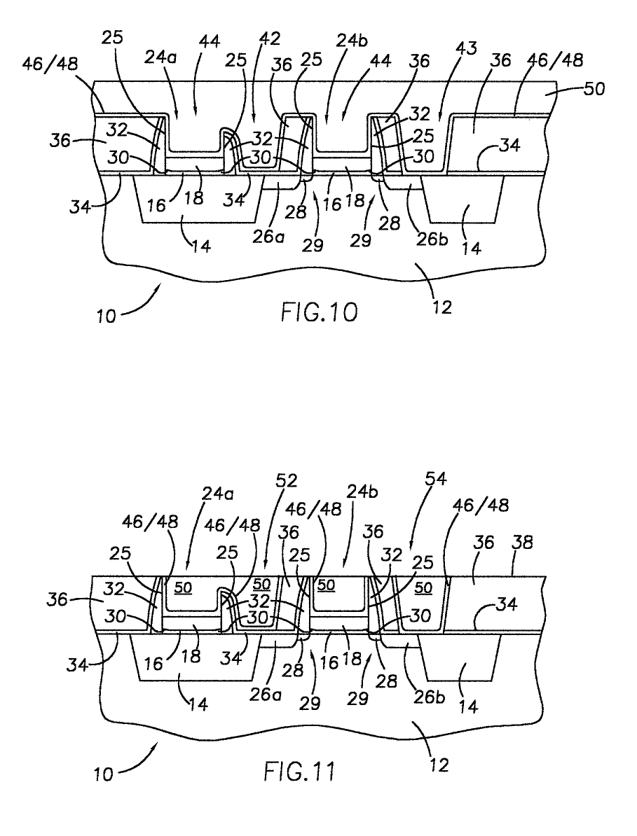

Referring to FIG. 10, a conductive material 50 is deposited over the contact layer 48 between the spacers 32 to fill recesses 44 in electrical connection with the first conductive layer 18. Simultaneously, the conductive material 50 is deposited over the contact layer 34 to fill the opening 42 and form a local interconnect 52 in electrical contact with gate stack 24a, and to fill the opening 43 and form pad 54 in electrical contact with source/drain structure 26b. Exemplary conductive materials for conductive material 46 comprise elemental metals, alloy metals and refractory metals including their metal silicates and nitrides. Preferably, conductive material 50 predominately comprises tungsten. Exemplary methods for forming conductive material 50 comprise PVD and/or CVD processes.

Referring to FIG. 11, portions of conductive material 50, diffusion barrier layer 46, and contact layer 48 are removed (preferably all diffusion barrier layer 46 and contact layer 48 over insulative layer 36 is removed). An exemplary method of removing conductive material 50 and layers 46/48 comprises CMP down to upper surface 38 of insulative layer 36. The transistor gates shown as gate stacks 24a,b now comprise at least two conductive layers of different conductive materials, one of the two conductive layers (i.e., layer 18) being more proximate the gate dielectric layer 16 than the other of the two conductive layers (i.e., layer 50). The transistor gates 24a,b in the preferred embodiment comprise of polysilicon, TiN and tungsten.

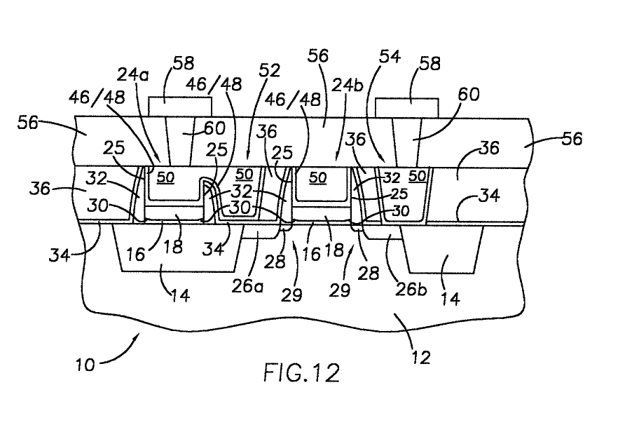

Referring to FIG. 12, additional processing comprises forming a dielectric layer 56 over insulative layer 36 and conductive material 50. Metal lines 58 are formed over a portion of dielectric layer 56. Conductive plugs 60 are previously formed which electrically connect the metal lines 58 to the source/drain regions 26a,b and transistor gates 24a,b.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

What is claimed:

1. A method of forming an interconnect structure in a semiconductor device, comprising the steps of:
providing a substrate comprising at least one transistor gate stack, source/drain regions, and an insulating layer adjacent the transistor gate stack; the transistor gate stack comprising a sacrificial layer overlying a first conductive layer;
removing a portion of the insulating layer to form an opening;
removing the sacrificial layer of the gate stack to form a recess over the first conductive layer; and
depositing a second conductive material to fill the recess of the transistor gate and the opening in the insulating layer to form the interconnect structure.

2. The method of claim 1, wherein the interconnect structure is selected from the group consisting of local interconnects, contacts, buried contacts, vias, plugs, contact landing pads, and filled trenches.

3. The method of claim 1, wherein in the step of removing the insulating layer, the opening is in communication with the sacrificial layer of the gate stack; and the interconnect structure is a local interconnect in electrical communication with the gate stack.

4. The method of claim 1, wherein in the step of removing the insulating layer, the opening is isolated from the gate stack and in communication with the source/drain region; and the interconnect structure is a contact landing pad.

5. The method of claim 1, wherein the sacrificial layer comprises silicon nitride.

6. The method of claim 1, wherein the first conductive layer comprises polysilicon.

7. The method of claim 1, wherein the second conductive layer comprises a conductive metal.

8. The method of claim 6, wherein the second conductive layer comprises tungsten; and the method further comprises, prior to the step of depositing the second conductive material, depositing a contact layer and an overlying diffusion barrier layer into the recess of the gate stack and into the opening in the insulating layer.

9. The method of claim 8, wherein the contact layer comprises titanium, and the diffusion barrier layer comprises titanium nitride.

10. The method of claim 8, wherein the transistor gate stack further comprises an intervening layer disposed between the sacrificial layer and the first conductive layer; and the contact layer is deposited onto the intervening layer.

11. The method of claim 10, wherein the intervening layer comprises a material selected from the group consisting of oxide, nitride, oxynitride, or a combination thereof.

12. The method of claim 1, wherein the insulating layer comprises borophosphosilicate glass.

13. The method of claim 1, wherein the step of removing the insulating layer to form the opening is by a dry etch process.

14. The method of claim 1, wherein the step of removing the sacrificial layer of the gate stack to form the recess is by a hot phosphoric acid strip.

15. The method of claim 1, wherein the second conductive material is deposited by physical vapor deposition.

16. A method of simultaneously forming a local interconnect structure and a gate stack in a semiconductor device, comprising the steps of:
providing a substrate comprising at least one transistor gate stack, source/drain regions, and an insulating layer adjacent the transistor gate stack; the transistor gate stack comprising a sacrificial layer overlying a first conductive layer;
patterning an opening in the insulating layer to correspond with the local interconnect; the opening in communication with the gate stack;
removing the sacrificial layer of the gate stack to form a recess; and
depositing a second conductive material to fill the recess of the transistor gate and the opening in the insulating layer to form the local interconnect structure; whereby the interconnect structure and the first conductive layer of the transistor gate stack are in electrical communication.

17. The method of claim 16, wherein the sacrificial layer comprises silicon nitride.

18. The method of claim 16, wherein the opening in the insulating layer is patterned by a photolithographical process.

19. The method of claim 16, wherein the sacrificial layer is removed by a hot phosphoric acid strip.

20. The method of claim 16, wherein the second conductive material comprises tungsten.

21. The method of claim 20, wherein the first conductive material comprises polysilicon.

22. A method of simultaneously forming a contact landing pad interconnect structure and a gate stack in a semiconductor device, comprising the steps of:
providing a substrate comprising at least one transistor gate stack, source/drain regions, and an insulating layer adjacent the transistor gate stack; the transistor gate stack comprising a sacrificial layer overlying a first conductive layer;
patterning an opening in the insulating layer to correspond to the pad interconnect structure; the opening in communication with the source/drain;
removing the sacrificial layer of the gate stack to form a recess; and
depositing a second conductive material to fill the recess of the transistor gate and the opening in the insulating layer to form the interconnect pad structure; whereby the interconnect pad structure and the source/drain are in electrical communication.

23. The method of claim 22, wherein the sacrificial layer comprises silicon nitride.

24. The method of claim 22, wherein the second conductive material comprises tungsten.

25. The method of claim 24, wherein the method further comprises, prior to the step of depositing the second conductive material, depositing a contact layer and an overlying diffusion barrier layer into the recess of the gate stack and into the opening in the insulating layer; wherein the contact layer is received over and in contact with the gate stack, the source/drain regions and the insulating layer.

26. The method of claim 25, wherein the contact layer comprises titanium, and the diffusion barrier layer comprises titanium nitride.

27. The method of claim 26, wherein the transistor gate stack further comprises an intervening layer interposed between the sacrificial layer and the first conductive layer; and the contact layer is deposited onto the intervening layer, and the intervening layer comprises a material selected from the group consisting of oxide, nitride, oxynitride, or a combination thereof.

28. The method of claim 27, wherein the step of removing the sacrificial layer comprises exposing the intervening layer; and the method further comprises, prior to the step of depositing the contact layer, the step of removing a portion of the intervening layer to expose the first conductive layer.

29. A method of forming an interconnect structure in a semiconductor device, comprising the steps of:
providing a substrate comprising a transistor gate stack, source/drain regions, and an insulating layer adjacent the transistor gate stack; the transistor gate stack comprising sidewall spacers formed laterally adjacent thereto, and a sacrificial layer overlying a first conductive layer;
removing a portion of the insulating layer to form an opening;
removing the sacrificial layer of the gate stack to form a recess;
forming a diffusion barrier layer over the gate stack, the source/drain regions and the insulating layer; and
depositing a second conductive material over the diffusion barrier layer to fill the recess of the transistor gate and the opening in the insulating layer to form the interconnect structure.

30. The method of claim 29, further comprising, prior to the step of forming the diffusion barrier layer, the step of forming a contact layer over the sacrificial layer.

31. The method of claim 30, wherein the contact layer comprises titanium.

32. The method of claim 31, wherein the diffusion barrier layer comprises titanium nitride.

33. The method of claim 29, wherein the gate stack further comprises an intervening layer disposed between the sacrificial layer and the first conductive layer.

34. The method of claim 33, wherein the contact layer is deposited onto the intervening layer.

35. The method of claim 34, wherein the intervening layer comprises a material selected from the group consisting of oxide, nitride, oxynitride, or a combination thereof.

36. The method of claim 29, wherein the interconnect structure is selected from the group consisting of local interconnects, contacts, buried contacts, vias, plugs, contact landing pads, and filled trenches.

37. The method of claim 29, wherein in the step of removing the insulating layer, the opening is in communication with the sacrificial layer of the gate stack; and the interconnect structure is a local interconnect in electrical communication with the gate stack.

38. The method of claim 29, wherein in the step of removing the insulating layer, the opening is isolated from the gate stack and in communication with the source/drain region; and the interconnect structure is a contact landing pad.

39. The method of claim 29, further comprising, after the step of depositing the second conductive material, the step of removing an excess portion of the conductive material to form the interconnect structure and the gate stack.

40. The method of claim 39, wherein the step of removing the conductive material is performed by chemical-mechanical polishing.

41. A method of forming a transistor and an interconnect structure; the transistor comprising a gate stack, a gate dielectric layer, source/drain regions, and an insulating layer adjacent the transistor gate stack; the transistor gate stack comprising overlying layers of a sacrificial layer, an intervening layer, and a first conductive layer; the method comprising the steps of:
patterning an opening in the insulating layer for the interconnect structure;
removing the sacrificial layer of the gate stack to form a recess and expose the intervening layer;
depositing a contact layer over the intervening layer, the source/drain regions and the insulating layer;
depositing a diffusion barrier layer over the contact layer; and
depositing a second conductive material over the diffusion barrier layer to fill the recess of the gate stack and the opening in the insulating layer to form the interconnect structure.

42. A semiconductor processing method of forming a transistor gate comprising insulative sidewall spacers formed laterally adjacent thereto, and a sacrificial layer overlying a first conductive layer; an insulative layer disposed adjacent to the sidewall spacers; the method comprising the steps of:
removing a portion of the insulating layer to form an opening;
removing the sacrificial layer of the gate stack to form a recess; and
depositing a second conductive material to fill the recess of the transistor gate and the opening in the insulating layer to form the interconnect structure.

43. The method of claim 42, wherein the transistor gate comprises a barrier layer disposed between the first and second conductive materials; and the first conductive material comprises polysilicon, and the second conductive material comprises tungsten.

44. A method of forming a transistor and an interconnect structure; comprising the steps of:
providing a substrate comprising a gate dielectric layer formed thereon and a conductive layer formed over the gate dielectric layer;
forming a sacrificial layer over the conductive layer;
at least partially forming source/drain regions;
forming a pair of sidewall spacers laterally adjacent the conductive layer and sacrificial layer;
forming an insulative layer over the sacrificial layer and the source/drain regions;
removing a portion of the insulative layer to expose the sacrificial layer;
patterning an opening in the insulating layer for the interconnect structure;
removing the sacrificial layer to expose the conductive layer; and
forming a layer predominately comprising elemental or alloy metal over the conductive layer and into the opening of the insulating layer.

45. The method of claim 44, wherein the sidewall spacers comprise silicon dioxide and the sacrificial layer comprises silicon nitride.

46. The method of claim 44, further comprising forming an intervening layer between the conductive layer and the sacrificial layer.

47. The method of claim 46, wherein the intervening layer comprises a material selected from the group consisting of oxide, nitride, oxynitride, or a combination thereof.

48. The method of claim 44, wherein the interconnect structure is selected from the group consisting of local interconnects, contacts, buried contacts, plugs, contact landing pads, and filled trenches.

49. A method of forming a transistor comprising:
sequentially forming a gate dielectric layer, a first conductive layer, and a sacrificial layer over a semiconductor substrate;
patterning the gate dielectric layer, the first conductive layer, and the sacrificial layer into a transistor gate stack;
forming insulative sidewall spacers over sidewalls of the gate stack;
forming an insulative layer over the sacrificial layer and the source/drain regions;
removing a portion of the insulative layer to expose the sacrificial layer;
patterning an opening in the insulating layer for the interconnect structure;
removing substantially all the sacrificial layer from the gate stack between the spacers; and
simultaneously depositing a conductive material between the spacers in electrical connection with the first conductive layer to form the transistor gate, and into the opening in the insulating layer to form the interconnect structure in electrical connection with the gate.

50. The method of claim 49, wherein the sacrificial layer comprises an insulative material.

51. The method of claim 49, further comprising, prior to forming the sacrificial layer, forming an intervening layer over the first conductive layer;
wherein removing the sacrificial layer comprises etching the sacrificial layer substantially selective to the intervening layer; and
prior to forming the second conductive material, removing a portion of the intervening layer to expose the first conductive layer.

52. The method of claim 49, wherein the conductive material comprises elemental or alloy metal.

53. The method of claim 49, further comprising forming a titanium nitride layer between the first conductive layer and the conductive material.

54. The method of claim 49, wherein the interconnect structure is selected from the group consisting of local interconnects, contacts, buried contacts, vias, plugs, contact landing pads, and filled trenches.

55. The method of claim 54, wherein in the step of removing the insulating layer, the opening is in communication with the sacrificial layer of the gate stack; and the interconnect structure is a local interconnect in electrical communication with the gate stack.

56. The method of claim 54, wherein in the step of removing the insulating layer, the opening is isolated from the gate stack and in communication with the source/drain region; and the interconnect structure is a contact landing pad.

57. A method of forming a transistor, comprising the steps of:
providing a substrate including a gate dielectric layer formed thereon and a conductive layer formed over the gate dielectric layer;
forming a sacrificial layer over the conductive layer;
at least partially forming source/drain regions;
forming a pair of sidewall spacers laterally adjacent the conductive layer and sacrificial layer;
removing the sacrificial layer to expose the conductive layer;
forming a layer predominately comprising elemental or alloy metal over the conductive layer;
removing a portion of the layer comprising elemental or alloy metal to define a recess over the conductive layer between a portion of the sidewall spacers; and
providing an insulative material within the recess.

58. A method of forming a transistor and an interconnect structure, the transistor comprising a transistor gate, a gate dielectric layer and source/drain regions, the transistor gate comprising at least two conductive layers of different conductive materials, a first conductive layer being more proximate the gate dielectric layer than the second conductive layer; the second conductive layer and the interconnect comprising tungsten, the method comprising the steps of:
forming a silicon nitride layer over the first conductive layer;
forming a dielectric layer over the silicon nitride layer and transistor gate, and adjacent to the transistor gate;
removing a portion of the dielectric layer to expose the silicon nitride layer and pattern an opening for the interconnect structure in the dielectric layer adjacent the transistor gate;
removing the silicon nitride layer and exposing the first conductive layer;
forming the second conductive layer comprising tungsten over the first conductive layer to form the transistor gate, and into the opening of the dielectric layer adjacent the transistor gate to form the interconnect structure.

59. The method of claim 58, wherein the interconnect structure is selected from the group consisting of local interconnects, contacts, buried contacts, vias, plugs, contact landing pads, and filled trenches.

60. The method of claim 58, wherein in the step of removing the dielectric layer, the opening for the interconnect structure is in communication with the transistor gate, and the interconnect structure is a local interconnect in electrical connection with the transistor gate.

61. The method of claim 58, wherein in the step of removing the dielectric layer, the opening for the interconnect structure is isolated from the transistor gate and in communication with the source/drain region, and the interconnect structure is a contact landing pad.

62. The method of claim 61, wherein the transistor gate further comprises an intervening layer interposed between the first and second conductive layers; and the step of removing the silicon nitride layer comprises exposing the intervening layer; and the method further comprises removing the intervening layer to expose the first conductive layer.
